(19) United States
(12) Patent Application Publication
(10) Pub. No.: US 2025/0357936 A1
(43) Pub. Date: Nov. 20, 2025

(54) PHASE-LOCKED LOOP CIRCUIT AND METHOD

(71) Applicant: STMicroelectronics International N.V., Geneva (CH)

(72) Inventors: Simone SCADUTO, Mussomeli (IT); Bruno CAVALLARO, Acireale (IT); Daniele CASELLA, Francofonte (IT); Agatino Antonino ALESSANDRO, Rho (MI) (IT); Sergio GAGLIOLO, Padova PD (IT)

(73) Assignee: STMicroelectronics International N.V., Geneva (CH)

(21) Appl. No.: 19/211,445

(22) Filed: May 19, 2025

(30) Foreign Application Priority Data
May 20, 2024 (IT) 102024000011317

(51) Int. Cl. H03L 7/089; H02M 3/07; H03L 7/099

(52) U.S. Cl. CPC H03L 7/0895; H02M 3/07; H03L 7/099

(57) ABSTRACT

A PLL circuit includes a phase detector, a charge pump, a filter, a voltage-controlled oscillator, and a feedback loop. The circuit further includes switch circuitry to switch between: a first PLL circuit configuration where the voltage-controlled oscillator receives a reference voltage as a voltage control signal, and the charge pump is decoupled from the phase detector, with a phase-lock control signal for oscillator regulated at the reference voltage, and a second circuit configuration where the charge pump is coupled to the phase detector and the phase-lock control signal is generated based on a phase difference detected by the phase detector and the phase-lock control signal from the charge pump is applied to the voltage-controlled oscillator as the voltage control signal.

### PRIORITY CLAIM

This application claims the priority benefit of Italian Application for Patent No. 102024000011317 filed on May 20, 2024, the content of which is hereby incorporated by reference in its entirety to the maximum extent allowable by law.

### TECHNICAL FIELD

The description relates to phase-locked loop (PLL) circuits.

### BACKGROUND

A phase-locked loop (PLL), also referred to as a phase lock loop, is a well-known circuit arrangement that generates an output signal having a phase in a fixed relationship to the phase of an input signal. A phase-locked loop is also known to be able to track an input frequency, in so far as phase tracking may also imply keeping equal input and output frequencies.

A common implementation of a phase-locked loop includes a phase detector (PD) driving a charge pump (CP), a voltage-controlled oscillator (VCO) driven by the charge pump via a filter such as a low-pass filter (LPF), and a feedback loop from the voltage-controlled oscillator (VCO) to the phase detector that may comprise a frequency divider (/N). The phase detector produces digital pulses whose width is proportional to a sampled phase error. The charge pump converts that digital error pulse into an analog error current. The low pass filter integrates the error current to generate a control voltage used by the VCO. This may be a low-swing, low phase noise oscillator with frequency proportional to control voltage, and the feedback loop generates a (possibly frequency divided by N (/N)) feedback clock for phase comparison with the reference.

When an internal clock is paced by an oscillator and it is desired that the system may start PLL operation with an external clock, a frequency jump from the current clock frequency (internal clock) to a PLL minimum frequency may occur in response to the PLL being enabled. Such a clock frequency discontinuity is a drawback hardly tolerable for certain applications.

Other issues may be related to the time involved in PLL lock-up while maintaining a smooth tracking of the external clock. Reducing such lock-up time is a significant factor for various applications.

In a solution that is easy to apply from the perspective of circuit implementation, an analog multiplexer is used to switch PLL operation from open-loop to closed-loop oscillation: the PLL starts operating at a fixed frequency which is increased until PLL lockup. The analog multiplexer is set to a reference voltage such that the PLL works in open loop without any kind of frequency regulation.

Such a solution may not dispense with an undesirable frequency jump from the internal programmed clock frequency to the lowest frequency desired for starting PLL operation. This frequency jump is recovered (only) when the target value is reached by the PLL operating at the same frequency of the external reference clock.

U.S. Pat. No. 9,106,128 B2 (incorporated herein by reference) discloses a charge pump circuit for a phase-locked loop having a current mirror structure, including a first voltage controller including a plurality of first resistors and a plurality of first switches. In response to a switching control signal corresponding to a bias current, the plurality of first switches are driven to allow a current path passing through the plurality of first resistors to bypass, thereby controlling a voltage level of an output end, a second voltage controller including a plurality of second resistors and a plurality of second switches, and in response to the switching control signal, driving the plurality of second switches to allow a current path passing through the plurality of second resistors to bypass, thereby controlling a voltage level of an output end to correspond to the voltage of the output end of the first voltage controller.

European Patent No. 2814176 A1 (incorporated herein by reference) discloses a fast lock PLL integrated circuit implementing a phase error reduction sequence during a wide bandwidth mode of operation of a loop filter module of the PLL, which sequence includes reducing parameter of a VCO module of the PLL. Since such control of the phase/frequency of the output signal of the VCO does not depend on current mismatch in, for instance, a charge pump of the PLL, a fast lock with low phase noise error can be achieved without requiring a complex mismatch cancellation system occupying a large die area.

Other documents illustrative of the related art include U.S. Pat. Nos. 7,292,106 B2, 11,664,810 B2, and 11,695,422 B2 and Chinese Patent reference Nos. CN 112260686 B, CN 112910460A, and CN117040528 A (all of which are incorporated here by reference).

To summarize, a short startup time and clock frequency linearity, namely the absence of a notable clock frequency variation (“frequency jump”) in the system clock, are desirable features in many system applications.

There is a need in the art to contribute in addressing the issues discussed in the foregoing.

### SUMMARY

The solutions described herein relate to a circuit.

The solutions described herein also relate to a corresponding method.

Solutions as described herein effectively counter frequency discontinuity when it is desired to switch between a free running mode (with an internal system clock) at a programmed frequency, to a PLL mode (paced by an external clock).

Solutions as described herein avoid starting a PLL locking phase with a frequency different from the (open loop) frequency of the VCO in the PLL: this was observed to lie at the basis of frequency discontinuity if PLL operation is started after the main system clock is already enabled.

To summarize, in the solutions described herein, the PLL is operated in a closed loop (also) when operating under an internal clock, keeping the PLL control node at a potential that corresponds to the potential that should be set by an external clock with same frequency of the internal clock.

Frequency changes of the clock are thus kept as smooth as possible by reducing and possibly removing undesired discontinuities by aligning the PLL frequency to a previously programmed frequency.

A converter such as a DC-DC converter, for instance, may be exemplary of systems (devices) where solutions as described herein can be applied advantageously. In these systems including a PLL, a discontinuity in the locking frequency may entail various disadvantages.

For instance, in the exemplary case of a DC-DC converter these disadvantages may include distortion in the regulated voltage (with voltage drops or spikes), malfunctioning of overcurrent and overvoltage protections and possible loss of stability.

Solutions as described herein contemplate an operation mode (tracking phase) that offers three notable advantages: soft PLL startup; undesired frequency swings are avoided in so far as similar frequencies are used for the external clock and for the internal, self-generated clock; and reduced locking time.

### BRIEF DESCRIPTION OF THE DRAWINGS

One or more embodiments will now be described, by way of example only, with reference to the annexed figures, wherein:

FIG. 1 is a block diagram exemplary of a PLL circuit architecture;

FIG. 2 is a block diagram exemplary of a PLL circuit architecture configured for both a free running mode of operation and a phase-locked mode of operation;

FIGS. 3A and 3B are diagrams showing possible time behaviors of signals that may occur in the circuit architecture as illustrated in FIG. 2;

FIG. 4 is a block diagram detailing certain features of the circuit architecture as illustrated in FIG. 2;

FIG. 5 is a block diagram exemplary of a PLL circuit architecture;

FIGS. 6A and 6B are diagrams showing possible time behaviors of signals that may occur in the circuit architecture as illustrated in FIG. 5;

FIGS. 7 and 8 are circuit diagrams that detail various possible implementation features of the circuit architecture as illustrated in FIG. 5.

### DETAILED DESCRIPTION

The figures are drawn to clearly illustrate the relevant aspects of the embodiments and are not necessarily drawn to scale.

The edges of features drawn in the figures do not necessarily indicate the termination of the extent of the feature.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

Also, for the sake of simplicity and ease of explanation, a same designation may be applied throughout this description to designate: a certain node or line as well as a signal occurring at that node or line, and/or a certain component (such as a capacitor, resistor or inductor of coil) as well as electrical parameters thereof.

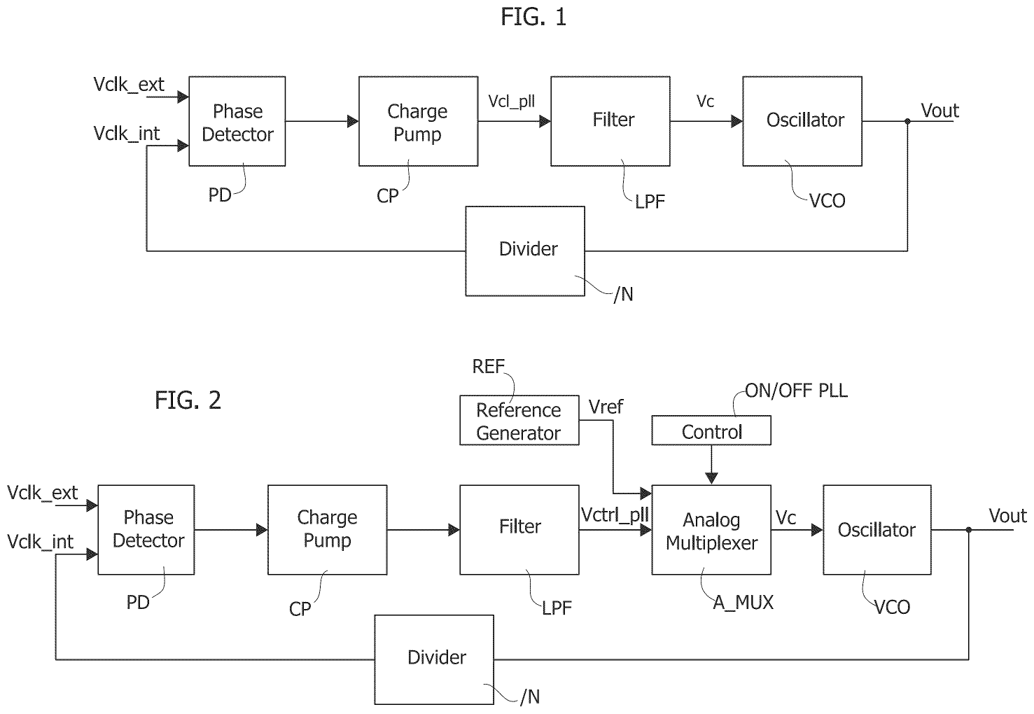

FIG. 1 is a general block diagram of a phase-locked loop (PLL) circuit.

As illustrated in FIG. 1, such a phase-locked loop (PLL) circuit includes a phase detector PD driving a charge pump CP, a voltage-controlled oscillator VCO driven by the charge pump via a filter such as a low-pass filter LPF, and a feedback loop from the voltage-controlled oscillator VCO to the phase detector PD that may comprise a frequency divider (referenced as /N).

The phase detector PD produces digital pulses whose width is proportional to a sampled phase error between an (external) input clock signal Vclk_ext and an (internal) feedback clock signal Vclk_int. The charge pump CP converts that digital error pulse into an analog error current. The low pass filter LPF integrates the error current to generate a control voltage Vc used by the voltage-controlled oscillator VCO. This may be a low-swing, low phase noise oscillator with frequency proportional to control voltage, and the feedback loop generates the feedback clock signal Vclk_int for phase comparison with the reference clock signal Vclk_ext. The feedback loop may comprise a block labeled /N configured to divide the VCO clock signal by a factor N, where N can be any integer value.

The VCO clock signal can be assumed to represent the output signal Vout from the PLL.

The diagram of FIG. 1 is exemplary of a wide class of different PLL circuits where solutions as described herein can apply.

These PLL circuits can thus be regarded as including: a phase detector PD having a first input and a second input, configured to detect a phase difference between an input clock signal Vclk_ext applied to the first input and a further clock signal Vclk_int applied to the second input; a charge pump CP configured to be coupled to the phase detector PD to produce (when coupled to the phase detector PD and possibly via a filter such as a low-pass filter LPF) to a phase-lock control signal Vcl_pll based on the phase difference detected by the phase detector (PD); a voltage-controlled oscillator VCO configured to produce at an output node a pulsed output signal Vout based on an oscillator voltage control signal Vc; and a feedback loop /N from the output node Vout of the voltage-controlled oscillator VCO to the second input of the phase detector PD wherein the further clock signal Vclk_int is a replica (frequency divided by a factor N, for instance) of the pulsed output signal Vout from the voltage-controlled oscillator VCO.

Structure and operation of a PLL circuit as discussed so far are well known to those of skill in the art and a further detailed description is not provided for brevity.

It is otherwise noted that the diagram of FIG. 1 is exemplary of a wide class of different PLL circuits where solutions as described herein can apply and which may include different features from those exemplified in FIG. 1: a different type of filter LPF or feedback loop /N can be mentioned as examples of such possible different features.

The designation “locking time” applies to the time interval taken by such a PLL circuit to lock a local clock in phase alignment with the external frequency clock Vclk_ext.

Oscillators that are configured to run both in a “free running mode” and in a “PLL mode” may give rise to issues related to the locking time and to a possible discontinuity in the frequency domain due switching between a self-programmed oscillator frequency and the PLL frequency.

For instance, in a possible scenario, the oscillator VCO starts operating at a programmed frequency with PLL operation enabled after some time. In that case, the PLL circuit generates a clock signal starting from a frequency that can be quite different from the oscillator programmed frequency. This behavior results in undesired frequency swings caused by phase jumps.

A smooth tracking of the external clock may affect the time needed for the PLL to lock up: reducing inasmuch as possible that time plays a key role in various applications.

A possible approach in reducing locking time is to set a minimum locking frequency under which the PLL-generated clock cannot be locked. For example, a minimum locking frequency can be set to 100 KHz so that when the PLL is enabled, an “instantaneous” clock is produced at a frequency of 100 KHz. This is used as a starting frequency for PLL locking. This implementation can be applied in systems where the VCO and the PLL start to work together, so that the VCO operates only in association with the PLL.

Such an approach avoids undesired frequency jumps at a system level but suffers from a problem related to startup time: if the starting frequency of the PLL is fixed, the resulting locking time is linked (proportional) to the external reference clock frequency.

A marked difference between the PLL starting frequency and the external clock frequency leads to a long time taken by the PLL to lock, with the locking time dictated primarily by the PLL filter bandwidth.

For instance, assuming that an external clock frequency of 200 KHz is selected with a PLL starting frequency of 100 KHz, a PLL locking time of T1 results. Conversely, if an external clock frequency of 2 MHz is selected with the same PLL starting frequency, a locking time T2 results that is much longer than T1.

A drawback of this approach becomes evident when the oscillator is running on a system internal clock and it is desired to start system operation with an external clock: when the PLL is enabled, a frequency jump occurs from the current clock frequency (internal clock) to the minimum frequency set for the PLL. For various systems, this clock frequency discontinuity is intolerable.

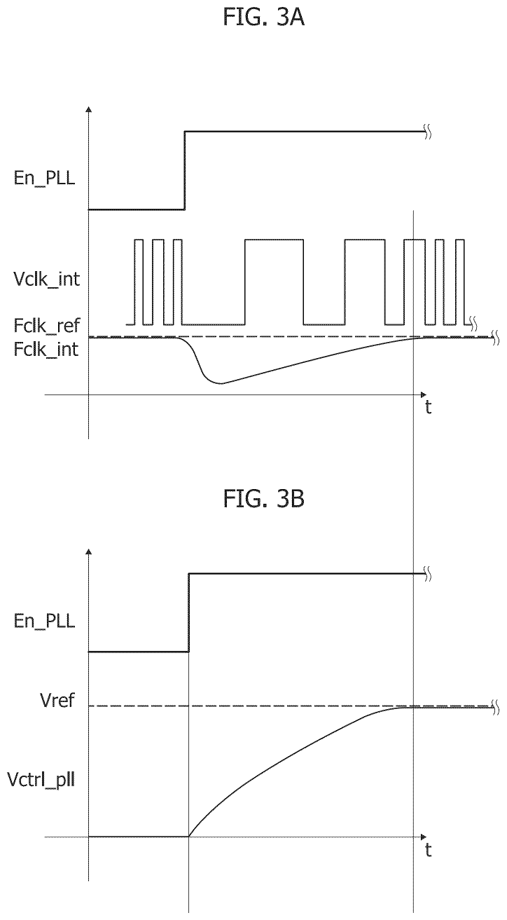

FIG. 2 is a general block diagram of a phase-locked loop (PLL) configured for open loop and close loop operation as discussed previously which is based on the general layout of FIG. 1.

For that reason, unless the context indicates otherwise, parts or elements like parts or elements already introduced in connection with FIG. 1 (phase detector PD, charge pump CP, loop filter LPF, voltage-controlled oscillator VCO, feedback loop including a frequency divider /N) are indicated in FIG. 2 with like reference symbols; a corresponding description will not be repeated for the sake of brevity.

Essentially, in the solution of FIG. 2 (which lends itself to be easily implemented from a circuit implementation perspective) an analog multiplexer A_MUX is arranged between the loop filter LPF and the voltage-controlled oscillator VCO.

The analog multiplexer A_MUX is configured to apply to the VCO a control voltage Vc which is selected (based on a control signal from a block labelled ON/OFF PLL) one signal out of: a reference signal Vref from a reference generation block REF (PLL OFF condition), or an output control signal Vctrl_pll from the loop filter LPF (PLL ON condition).

In an arrangement as illustrated in FIG. 2, the analog multiplexer A_MUX is used to switch from open loop to closed loop oscillation, enabling PLL operation.

That is, the PLL circuit starts operating from a fixed frequency with the PLL control node (the signal Vctrl_pll) increased until PLL lockup. When the analog multiplexer A_MUX is set to the reference voltage Vref, the PLL works in an open loop without any kind of frequency regulation.

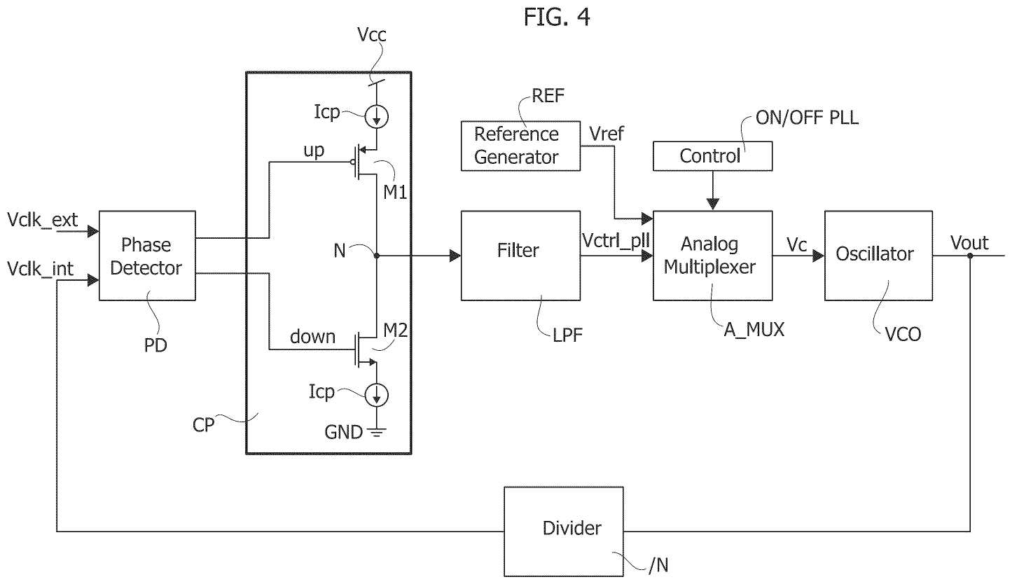

FIG. 3A and FIG. 3B are exemplary of possible operation of an arrangement as illustrated in FIG. 2 when switching from open-loop to closed-loop operation.

That is: before a signal En_PLL from the control block ON/OFF PLL is asserted from “0” to “1”, the VCO is working in free running mode using as the signal Vref as a reference; after a time, the signal En_PLL from the block ON/OFF PLL is asserted from “0” to “1”, thus indicating that the PLL is desired to be enabled and locked-up based on an external clock made available with the same frequency of the VCO oscillator.

FIG. 3A and FIG. 3B represent (against a common abscissa time scale t) possible time behaviors (waveforms) of signals that may occur in an arrangement as illustrated in FIG. 2 in response to PLL operation enabled by the signal En_PLL being asserted from “0” to “1”.

Specifically, FIG. 3A represents possible time behaviors of (from top to bottom): the enabling signal En_PLL; the signal Vclk_int fed to the phase detector PD; the frequency Fclk_ext of the external reference signal Vclk_ext equally fed to the phase detector PD plotted (in dashed line) against the frequency Fclk_int of the internal reference signal Vclk_int.

Consistently, FIG. 3B represents possible time behaviors of (from top to bottom): the enabling signal En_PLL; the (constant) reference signal Vref from the reference generator block REF; and the signal Vctrl_pll from the loop filter LPF.

When EN_PLL is 1, the analog mux A_MUX provides the VCO with the (voltage) signal Vctrl_pll instead of the voltage Vref.

Under these conditions: the PLL starts operating with a minimum allowed frequency, given by a minimum “clamp” voltage for Vctrl_pll (illustrated as zero for simplicity of representation), and the frequency evolves over time until the clock frequency generated by the VCO equals the external reference clock frequency Vref.

An undesirable frequency jump from the frequency programmed for the internal clock to the minimum allowed frequency occurs when the PLL starts to operate. This frequency jump is recovered (only) in response to the voltage Vctrl_pll reaching the target value corresponding to the same frequency oscillation of the external reference clock Vref.

As discussed, a reduced startup time and clock frequency linearity (the absence of considerable clock frequency variations or “jumps”) in a main system clock are desirable features in various system applications.

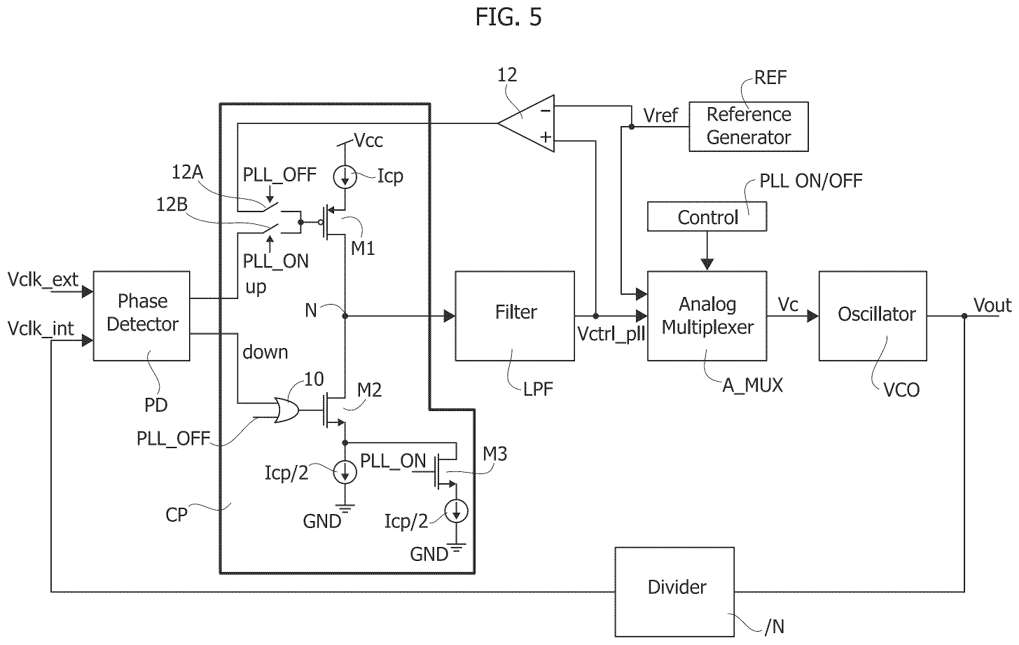

Solutions as described herein in connection with figures from FIG. 4 onwards effectively counter frequency discontinuities likely to result from switching between a free running mode of an oscillator paced by an internal system clock at a programmed frequency to a PLL mode locked to an external clock.

Solutions as described herein avoid starting a PLL locking phase with a frequency different from the VCO open loop frequency, in so far as this behavior leads to frequency discontinuity when a PLL mode is started when a main system clock is already enabled.

An underlying concept of solutions as described herein is thus to cause the PLL to work in closed-loop configuration (also) when the system is operated with an internal clock: this may involve a sort of “tracking phase” wherein a PLL control node (essentially, the input to the VCO) is kept at the same potential that might result from an external clock set at the same frequency of the internal one.

This approach was found to offer three significant advantages: soft PLL startup; undesired frequency swings are countered in response to an external clock having frequency similar to the frequency of an internal self-generated clock; and reduced locking time.

The block diagram of FIG. 4 develops on the PLL architecture as discussed in connection with FIG. 2.

For that reason, unless the context indicates otherwise, parts or elements like parts or elements already introduced in connection with FIGS. 1 and 2 (phase detector PD, charge pump CP, loop filter LPF, voltage-controlled oscillator VCO, frequency divider /N) are indicated in FIG. 4 with like references symbols; a corresponding description will not be repeated for the sake of brevity.

The diagram of FIG. 4 essentially details possible architecture of a PLL charge pump CP comprising two electronic switches M1 and M2 (MOSFET transistors, for instance) arranged with the current flow paths therethrough (source-drain paths in the case of field effect transistors such as MOSFET transistors) cascaded in series between a supply rail or node at voltage Vcc and ground GND.

The control electrodes (gates in the case of field effect transistors such as MOSFET transistors) are driven via “up” and “down” signals from the output of the phase detector PD.

A node N, which—after filtering in the loop filter LPF—provides a control signal Vctrl_pll suited to be applied (via the multiplexer A_MUX) as a PLL control node (signal Vc) to the oscillator VCO is charged/discharged via the transistors M1 and M2 based on the (phase) difference between the signals Vclk_ext and Vclk_int.

It was observed that, in addition to being exploited as a switch, the transistor M1 can act as a pass device for a sort of voltage regulator acting on the node N to set the voltage Vctrl_pll for the oscillator VCO.

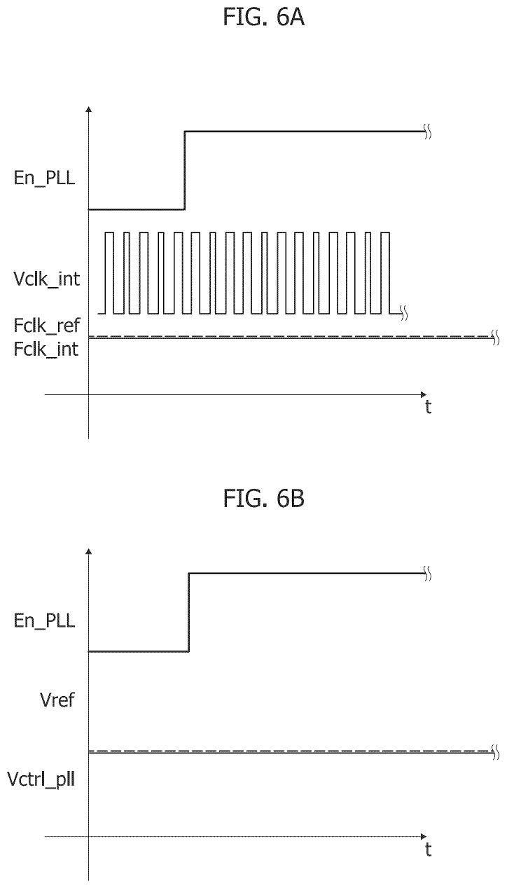

This may involve modifying the circuit arrangement of FIG. 4 as exemplified in FIG. 5: for ease of explanation and understanding (and unless the context indicates otherwise) parts or elements like parts or elements already introduced in connection with FIGS. 1, 2 and 4 will be indicated in figures from FIG. 5 onwards with like references symbols; a corresponding description will not be repeated for the sake of brevity.

Also, various switches are shown in FIG. 5 that are assumed to be turned “on” (made conductive) in response to an associated control signal PLL_ON/PLL_OFF being set to “1”. These signals are generated (in a manner known per se to those skilled in the art) in the block ON/OFF PLL and can be assumed to be generally complementary to each other, so that PLL_OFF=1 will correspond to PLL_ON=0 and PLL_OFF=0 will correspond to PLL_ON=1.

In the circuit arrangement exemplified in FIG. 5, the charge pump CP is modified in such a way that the charge pump switch M1 can be used (also) as a regulator pass device when the system is paced by an internal clock.

In that case, the switch M2 can be switched (forced) to an “on” state (conductive).

That result can be achieved by coupling the control terminal of the switch M2 (gate in the case of a field-effect transistor such as a MOSFET transistor) to receive the signal output from an OR gate 10 that receives as its inputs: the down signal from the phase detector PD (in the case of a phase-locked mode of operation proper); and a signal PLL_OFF from the control block PLL ON/OFF (in the case of a free running mode of operation).

In this latter case, when the system is paced by an internal clock (PLL operation disabled) one may thus assume that the signal PLL_OFF is set to “1” so that the switch M2 is conductive irrespective of the value of the down signal from the phase detector PD.

As illustrated in FIG. 5, a further electronic switch M3 (a MOSFET transistor for instance) is coupled to the current flow path (source-drain in the case of a field-effect transistor such as a MOSFET transistor) with: the switch M2 arranged between the node N and the switch M3, and the switch M3 between the switch M2 and ground GND.

A signal PLL_ON (complementary to the signal PLL_OFF) is applied to the control electrode (gate in the case of a field-effect transistor such as a MOSFET transistor) of the transistor M3.

In that way, when PLL_OFF is “1”, PLL_ON is “0” and the switch M3 is off (non-conductive) to implement the voltage regulation with a current Icp (suited to be modulated) flowing through the switch M2.

Conversely, when (as discussed in the following) PLL_OFF is “0”, PLL_ON is “1”, the switch M3 is on (made conductive) and may take a fraction essentially equal to Icp/2 of the current Icp that flows through the switch M2 when this is turned “on” (made conductive) by the signal down from the phase detector PD.

As illustrated in FIG. 5, a differential stage 12 such as an operational amplifier (OpAmp or OPA) can be arranged having applied to its inputs the reference signal Vref from the block REF (inverting input, for instance) and the signal VCrtl_pll intended to be applied to the oscillator VCO (non-inverting input, for instance).

The differential stage 12 thus implements a voltage regulator using the switch M1 as a pass device.

To that effect, the output from the differential stage 12 (here Vctrl_pll−Vref) is applied to the control terminal of the switch M1 (gate in the case of a field-effect transistor such as a MOSFET transistor) via a switch 12A that is closed (made conductive) in response to the signal PLL_OFF=1.

The control terminal of the switch M1 receives the signal up from the phase detector PD in response a further switch 12B being closed (made conductive) in response to the signal PLL_ON=1.

In that way, when PLL_OFF is “1”, PLL_ON is “0” and the control terminal of the switch M1 receives the output from the differential stage 12 (here Vctrl_pll−Vref) to implement the voltage regulation with a current Icp flowing through the switch M2.

Conversely, when (as discussed in the following) PLL_OFF is “0”, PLL_ON is “1”, the switch M1 is traversed by a current equal to Icp when the switch M1 is turned “on” (made conductive) by the signal up from the phase detector PD.

In the condition where PLL_OFF is “1” and PLL_ON is “0” the PLL control node (the signal Vctrl_pll) is forced to be at the same reference voltage Vref provided to the oscillator VCO.

Stated otherwise, in this “free running” mode of operation (PLL_OFF=1), the signal Vctrl_pll at the PLL control node is forced to a same potential as in the case of a PLL operating in closed loop (PLL_ON=1) with a clock input reference frequency corresponding to the frequency produced by the oscillator VCO.

To summarize, the circuit exemplified in FIG. 5 comprises switch circuitry, namely the switches referenced as PLL_ON, PLL_OFF plus the multiplexer A_MUX (in co-operation with the OR gate 10), configured to switch operation of the circuit from a first configuration (“free running mode”) to a second configuration (“PLL mode proper”).

In the first circuit configuration: the voltage-controlled oscillator VCO is configured to receive (via the multiplexer A_MUX) a reference voltage Vref as the voltage control signal Vc; the charge pump CP is operatively decoupled from the phase detector PD (in so far as the signal “up” from the phase detector PD does not propagate to the gate of the MOSFET transistors M1 through the switch PLL_ON, which is open and thus non-conductive, and the gate of the MOSFET M2 is forced to “1” by the signal PLL_OFF via the OR gate 10 irrespective of the value the signal “down” from the phase detector PD); and the charge pump CP is configured to regulate (via the Op-amp 12 and the MOSFET transistor M1 as a pass device) the phase-lock control signal Vctrl_pll at the reference voltage Vref.

Conversely, in the second circuit configuration: the charge pump CP is operatively coupled to the phase detector PD and produces (via the filter LPF) the phase-lock control signal Vctrl_pll based on the phase difference detected by the phase detector PD; and the phase-lock control signal Vctrl_pll from the charge pump CP is applied (via the filter LPF and the multiplexer A_MUX) to the voltage-controlled oscillator VCO as the voltage control signal Vc.

To summarize, the circuit exemplified in FIG. 5 retains certain basic features of a PLL circuit such as: a phase detector PD having a first input and a second input, configured to detect a phase difference between an input clock signal Vclk_ext applied to the first input and a further clock signal Vclk_int applied to the second input; a charge pump CP configured to produce a phase-lock control signal Vctrl_pll; a voltage-controlled oscillator VCO configured to produce at an output node a pulsed output signal Vout based on an oscillator voltage control signal Vc applied thereto; and a feedback loop /N from the output node Vout of the voltage-controlled oscillator VCO to the second input of the phase detector PD wherein the further clock signal Vclk_int is a replica of the pulsed output signal Vout from the voltage-controlled oscillator VCO.

The circuit exemplified in FIG. 5 retains from a PLL circuit as illustrated in FIG. 2 the possible presence of a multiplexer A_MUX coupled to the voltage-controlled oscillator VCO to apply thereto a voltage control signal Vc selected out of: the reference voltage Vref in the first (“free running”) circuit configuration, and the phase-lock control signal Vctrl_pll from the charge pump CP in the second (PLL proper) circuit configuration.

As illustrated a filter (advantageously a low-pass filter LPF) is provided to filter the phase-lock control signal Vctrl_pll from the charge pump CP.

The circuit exemplified in FIG. 5 takes advantage of the fact that (as noted in connection with FIG. 4) the charge pump CP comprises a first electronic switch M1 and a second electronic switch M2 arranged in series (cascaded) in a common current flow line from the supply voltage Vcc to ground GND with a node N on the common current flow line between the first electronic switch M1 and the second electronic switch M2.

In the circuit exemplified in FIG. 5, in the second circuit configuration (PLL mode proper), in response to the charge pump CP being coupled to the phase detector PD, the first electronic switch M1 and the second electronic switch M2 are configured to be alternately made conductive and non-conductive wherein the phase-lock control signal Vctrl_pll is produced based on the phase difference detected by the phase detector as derived (via the filter LPF) from the node N on the common current flow line between the first electronic switch M1 and the second electronic switch M2 in the charge pump CP.

In the circuit exemplified in FIG. 5, the differential stage 12 is provided having inputs configured to receive as inputs the reference voltage Vref and the phase-lock control signal Vctrl_pll derived (via the filter LPF) from the node N on the common current flow line between the first electronic switch M1 and the second electronic switch M2.

However, in the first circuit configuration (“free running mode”), in response to the charge pump CP being decoupled from the phase detector PD, the output from the differential stage 12 is applied to the control terminal of the first electronic switch M1 in the charge pump CP wherein, in the first circuit configuration, the phase-lock control signal Vctrl_pll is regulated to the reference voltage Vref.

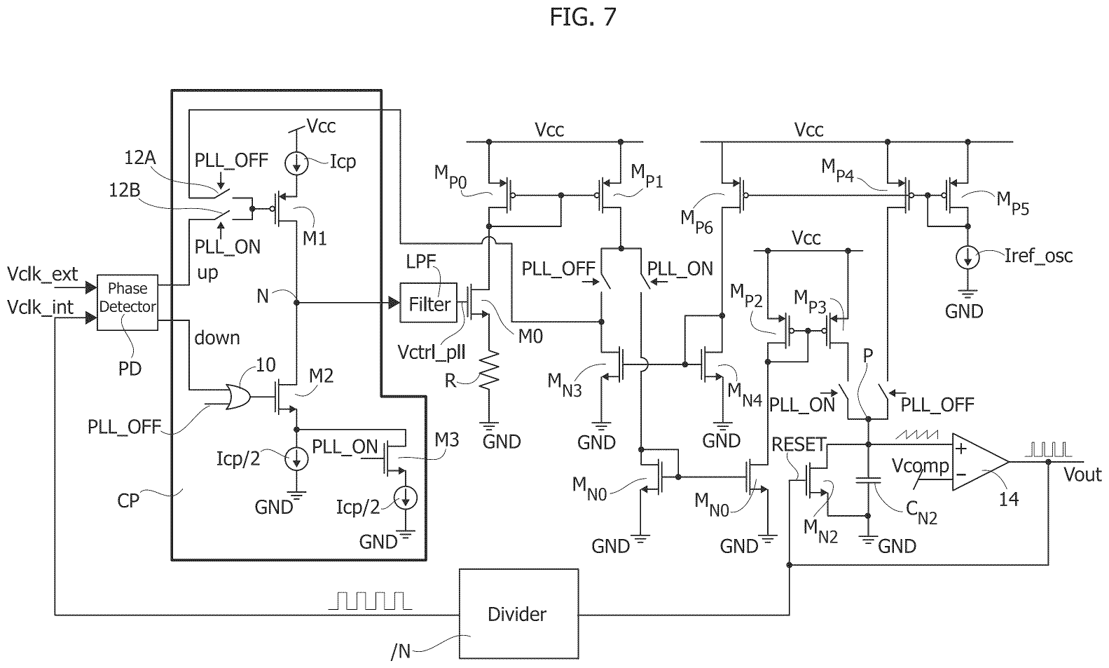

FIG. 6A and FIG. 6B represent (against a common abscissa time scale t) possible time behaviors (waveforms) of signals that may occur in an arrangement as illustrated in FIG. 5 in response to PLL operation enabled by the signal En_PLL being asserted from “0” to “1” (that is switching from PLL_OFF=1; PLL_ON=0 to PLL_OFF=0; PLL_ON=1 so that when EN_PLL is 1, the analog mux A_MUX provides the VCO with the (voltage) signal Vctrl_pll instead of the voltage Vref.

Specifically, FIG. 6A represents possible time behaviors of (from top to bottom): the enabling signal En_PLL; the signal Vclk_int fed to the phase detector PD; and the frequency Fclk_ext of the external reference signal Vclk_ext equally fed to the phase detector PD plotted (in dashed line) against the frequency Fclk_int of the internal reference signal Vclk_int.

Consistently, FIG. 6B represents possible time behaviors of (from top to bottom): the enabling signal En_PLL; the (constant) reference signal Vref from the block REF (in dashed line); and the signal Vctrl_pll from the loop filter LPF.

Before En_PLL is set to “1”, the oscillator VCO operates in a free running mode using the signal Vref as a reference Vref. During this phase, the PLL is in a tracking mode in so far as the signal Vctrl_pll is at the same level of the voltage Vref.

When a request to enable and lockup the PLL is asserted (PLL_ON=1) the voltage Vctrl_pll is already set to the “correct” voltage level.

As a first consequence, the PLL takes no extra time as possibly involved in charging the node Vcrtl_pll from a voltage set more or less arbitrarily in order to reach the target value to lock PLL with reference input clock.

Indeed, the PLL can start directly from a correct voltage level Vctrl_pll; this mechanism causes the PLL to start in a condition where it is immediately locked the external clock without any relevant frequency jump.

Another advantage is that the locking time will be drastically reduced: if the internal programmed clock frequency is close to the external clock frequency, the system will not exhibit any appreciable locking time. Moreover, the frequency clock transition is very smooth.

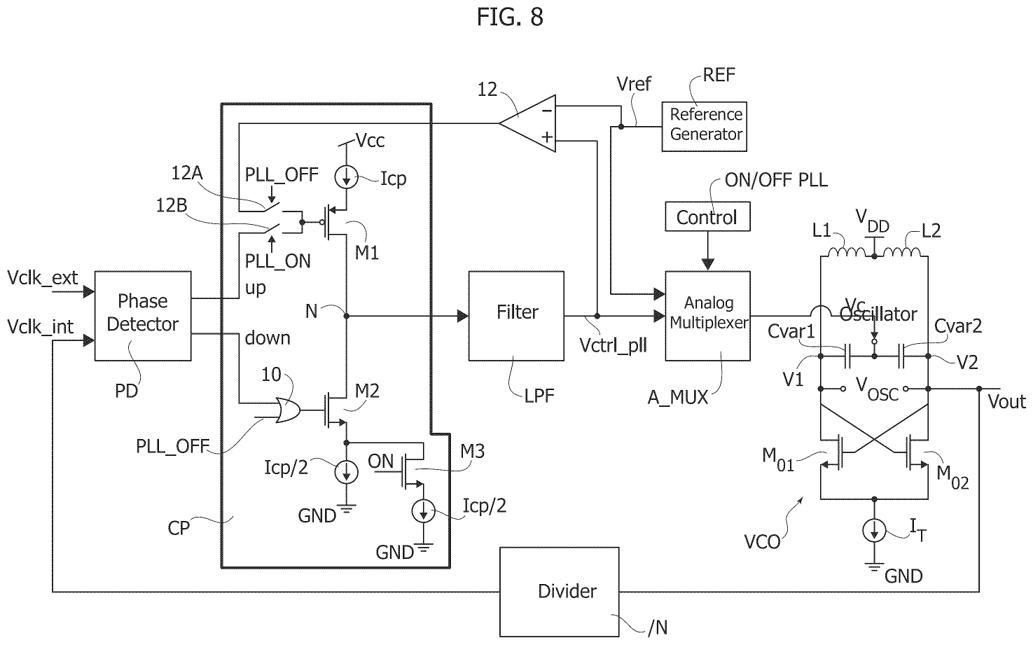

The circuit diagram of FIG. 7 illustrates a possible implementation of the circuit of FIG. 6 using an I/C (current/capacitor) oscillator VCO that may be implemented as further detailed in FIG. 8.

For ease of explanation and understanding (and unless the context indicates otherwise) parts or elements like parts or elements already introduced in connection with FIGS. 1, 2, 4 and 5 will be indicated in FIG. 7 onwards with like references symbols and a corresponding description will not be repeated for the sake of brevity.

Again, various switches are shown in FIG. 7 that are assumed to be turned “on” (made conductive) in response to an associated control signal PLL_ON/PLL_OFF being set to “1”.

These signals are generated (in a manner known per se to those skilled in the art) in the block ON/OFF PLL and can be assumed to be generally complementary to each other, so that PLL_OFF=1 will correspond to PLL_ON=O and PLL_OFF=0 will correspond to PLL_ON=1.

The circuit diagram of FIG. 7 can be regarded as including two different parts: a first part of the circuit diagram can be regarded as correspond presenting an otherwise conventional IC oscillator plus PLL including a phase detector PD, a low pass filter LPF and a VCO oscillator; and a second part of the circuit comprises those parts or elements that represent modifications made to the circuit in order to implement operation as discussed previously in connection with FIGS. 5, 6A, and 6B.

For simplicity, in the circuit diagram of FIG. 7, the phase detector PD, the low pass filter LPF, and the feedback loop /N are illustrated simply as boxes, and the charge pump CP is essentially as discussed in connection with FIG. 5: for brevity no related description will therefore be repeated in connection with FIG. 7.

In FIG. 7, the low pass filter LPF is held to apply the signal Vctrl_pll to VCO oscillator circuitry starting from the control terminal (gate in the case of a field-effect transistor such as MOSFET transistor) of a MOSFET transistor M0.

The MOSFET transistor M0 is arranged with the current flow path therethrough (source-drain, in the case of a field-effect transistor such as MOSFET transistor) included a current flow line from the supply rail Vcc and ground GND comprising the cascaded (series) arrangement of: the current flow path (source-drain, in the case of a field-effect transistor such as MOSFET transistor) through a diode-connected MOSFET transistor M_{P0} that is gate-to-gate coupled in a current mirror arrangement with a MOSFET transistor M_{P1}; the current flow path (source-drain) through the MOSFET transistor M0 (advantageously, this is n-channel if M_{P0} p-channel); and a resistor R.

The current flow path (source-drain, in the case of a field-effect transistor such as MOSFET transistor) through the MOSFET transistor M_{P1} is cascaded with the current flow path (source-drain, in the case of a field-effect transistor such as MOSFET transistor) through a diode-connected MOSFET transistor M_{N0} (advantageously, this is n-channel if M_{P1} is p-channel) that is in turn gate-to-gate coupled in a current mirror arrangement with a MOSFET transistor M_{N1}, in a further current flow line from the supply rail Vcc and ground GND.

A switch controlled by the signal PLL_ON in included in that further current flow line at a position intermediate the MOSFET transistors M_{P1} and M_{N0}.

The MOSFET transistor M_{N1} is arranged with the current flow path therethrough (source-drain, in the case of a field-effect transistor such as MOSFET transistor) cascaded in series in a current flow line from the supply rail Vcc and ground GND with the current flow path (source-drain, in the case of a field-effect transistor such as MOSFET transistor) through a diode-connected MOSFET transistor M_{P2} (advantageously, this is p-channel if M_{N1} is n-channel) that is in turn gate-to-gate coupled in a current mirror arrangement with a MOSFET transistor M_{P3}.

The MOSFET transistor MP3 is arranged with the current flow path therethrough (source-drain, in the case of a field-effect transistor such as MOSFET transistor) cascaded in series in a current flow line from the supply rail Vcc and ground GND with the current flow path (source-drain, in the case of a field-effect transistor such as MOSFET transistor) through a MOSFET transistor M_{N2} (advantageously, this is n-channel if MP3 is p-channel).

Across the current flow path through (source-drain, in the case of a field-effect transistor such as MOSFET transistor) the MOSFET transistor M_{N2} there is arranged (referred to ground GND) a capacitor C_{N2} onto which a ramp (sawtooth) signal is charged at a node P which is compared in an output comparator 14 with a reference threshold Vcomp to provide a pulsed output signal Vout.

The output signal Vout is returned as a RESET signal to the control terminal of the MOSFET transistor M_{N2} to periodically reset the ramp signal at the node P.

More to the point, the pulsed output signal Vout is applied to a frequency divider /N in the feedback loop to provide the signal Vclk_Int to the phase detector PD.

The references M_{P4} and M_{P5} denote two further MOSFET transistors gate-to-gate coupled in a current mirror arrangement.

Further coupling of the gates of the MOSFET transistors M_{P4} and M_{P5} (this latter being diode-coupled and configure to provide a current Iref_osc referred to ground GND) will be discussed in the following.

The node P at which the ramp-like (sawtooth) signal underlying the generation of the pulse output signal Vout occurs is coupled: via a switch controlled by the signal PLL_ON, to the current flow path (source-drain) through the MOSFET transistor M_{P3}; and via a switch controlled by the signal PLL_OFF, to the current flow path (source-drain) through the MOSFET transistor MP4.

The second part of the circuit of FIG. 7 groups those parts or elements that represent modifications made to implement operation as discussed previously in connection with FIGS. 5, 6A, and 6B. Further to the modifications made to the charge pump CP already discussed in connection with FIG. 5, that second part of the circuit of FIG. 7 includes: a diode-connected MOSFET transistor M_{N3} coupled in a gate-to-gate current mirror arrangement with a MOSFET transistor M_{N4}; and a further MOSFET transistor M_{P6} (advantageously, this is p-channel if M_{N4} is n-channel) gate-to-gate coupled with both MOSFET transistors M_{P4} and M_{P5}: that is, the MOSFET transistors M_{P4}, M_{P5}, and M_{P6} have their gates mutually coupled.

The MOSFET transistor M_{N3} is arranged with source-drain current flow path therethrough cascaded in series in a current flow line from the supply rail Vcc and ground GND with the source-drain current flow path through the MOSFET transistor M_{P1} (advantageously, this is p-channel if M_{N3} is n-channel) with a switch controlled by the signal PLL_OFF.

A node between that switch and the MOSFET transistor M_{N3} is coupled to the control electrode (gate, in the case of a field-effect transistor such as a MOSFET transistor) of the transistor M1 via a switch controlled by the signal PLL_OFF.

The MOSFET transistor M_{N4} is arranged with the source-drain current flow path therethrough cascaded in series in a current flow line from the supply rail Vcc and ground GND with the source-drain current flow path through the MOSFET transistor M_{P6} (advantageously, this is p-channel if M_{N4} is n-channel).

When PLL operation is disabled (PLL_ON=0, PLL_OFF=1) the clock frequency of the VCO oscillator is proportional to the current Iref_osc (through the MOSFET transistor M_{P5}). A copy of this current can be used as feedback for the voltage regulator when PLL is in tracking mode.

In that way, the voltage Vctrl_pll (PLL control node) can be kept at (or at least in the vicinity of) the same potential that would be reached with an external reference clock having the same frequency of the clock generated by the I/C VCO oscillator.

When the PLL is in such a tracking mode, closed-loop feedback is implemented in order to make the current provided by the PLL equal to Iref_osc.

When the PLL starts to operate with a reference clock (PLL_ON=1, PLL_OFF=0), the Vctrl_pll control node is already correctly set, and the VCO oscillator does not exhibit frequency jumps.

FIG. 8 details a possible implementation of solutions as disclosed herein wherein the oscillator VCO includes a cross-coupled oscillator with integrated center taped inductors.

Just like the circuit diagram in FIG. 7, the circuit diagram of FIG. 8 can be regarded as including two different parts: a first part of the circuit diagram of FIG. 8 can be regarded as presenting an otherwise conventional IC oscillator plus PLL including a phase detector PD, a low pass filter LPF, a feedback loop /N plus a VCO oscillator for which an advantageous implementation is presented in detail; and a second part of the circuit diagram of FIG. 8 comprises those parts or elements that represent modifications made to the circuit in order to implement operation as discussed previously.

For ease of explanation and understanding (and unless the context indicates otherwise) the representation of FIG. 8 goes back to the more synthetic representation of FIG. 5: in any case, parts or elements like parts or elements already introduced in connection with FIGS. 1, 2, 4, 5 and 7 are indicated in FIG. 8 with like references symbols and a corresponding description will not be repeated for the sake of brevity.

In the diagram of FIG. 8, the voltage Vc from the multiplexer A_MUX (which can be either the voltage reference Vref from the reference block REF or the “PLL node” voltage from the charge pump CP via the filter LPF) is applied to an intermediate node between two variable capacitors Cvar1, Cvar2 that can be advantageously implemented as CMOS varactors.

A varicap or varactor diode is a semiconductor diode having a junction capacitance that varies with varying the reverse bias voltage, thus facilitating a behavior as a variable capacitor, wherein the diode nature takes second place.

Opposite the common node therebetween, the capacitors Cvar1, Cvar2 are coupled to respective parallel current flow lines between a voltage rail at a voltage V_{DD} and ground GND via a “tail” current generator I_{T}.

In each such current flow line there is included the series connection of: an inductor—L1 and L2, respectively—having a first end coupled to the voltage rail V_{DD} and a second end coupled to a respective one of the capacitors Cvar1, Cvar2; and a current flow path (source-drain, in the case of a field-effect transistor such as a MOSFET transistor) through an electronic switch such as a MOSFET transistor M₀₁ and M₀₂.

The MOSFET transistors L1 and L2 are in cross-coupled arrangement wherein: the control terminal (gate, in the case of a field-effect transistor such as a MOSFET transistor) of the MOSFET transistor M₀₁ is coupled at a node V2 to the current flow path through the MOSFET transistor M₀₂ (and thus to the node Vout and to the capacitor Cvar2 opposite the node receiving the signal Vc), and the control terminal (gate, in the case of a field-effect transistor such as a MOSFET transistor) of the MOSFET transistor M₀₂ is coupled at a node V1 to the current flow path through the MOSFET transistor M₀₁ (and thus to the capacitor Cvar1 opposite the node receiving the signal Vc).

When PLL_OFF=1, PLL_ON=0 the clock frequency of the voltage Vout generated between the nodes V1 and V2 is proportional to the reference voltage across the capacitors Cvar1, Cvar2 (e.g., CMOS varactors).

Such a reference voltage is used also as feedback for the voltage regulator including the differential stage 12 (opamp) as error amplified and the MOSFET transistor M1 as regulator pass device. In that way the PLL control node (voltage Vctrl_pll) can be “regulated” at the voltage Vref.

When the PLL starts operate with a reference clock (namely PLL_OFF=0, PLL_ON=1) the Vctrl_pll control node is already set at a desired value and the oscillator does not present frequency jumps.

Operation was first simulated of a circuit with an I/C oscillator VCO enabled and forced to work in a “free running” open loop mode at a programmed frequency of 1.9 MHz with PLL closed loop operation disabled.

An external reference clock, with the same frequency of the internal clock is assumed and, at 100 us after start, PLL operation was activated, with the PLL starting to operate at its minimum settled frequency. The PLL control node was forced to a fixed defined voltage level when PLL was enabled. Under these conditions a frequency jump was observed in response to PLL operation being started. The oscillator frequency was observed to drop to 600 KHz and with time taken in recovering and achieving phase alignment with the reference clock. No smooth transition could be observed with nearly 50 us needed to obtain generation of a correct clock frequency

Operation was then simulated of a circuit (again with an I/C oscillator VCO) with the oscillator is enabled and forced to work a programmed frequency of 1.9 MHz.

Also in this case, PLL operation was disabled at first but with the circuit (essentially the charge pump CP) configured to operate as a voltage regulator in a tracking phase as discussed herein.

An external reference clock, with the same frequency of the internal clock, is present and at 100 us PLL operation was enabled. In this case PLL operations is started with the PLL control node already at a correct voltage level. Under these conditions no frequency jumps were observed in response to starting PLL operation, with the oscillator frequency immediately phase-aligned with the reference clock.

A smooth transition was observed along with negligible time needed to generate a correct clock frequency. The transition was observed to be free of discontinuities, with no ripple change on Vout and on coil current. This is in contrast with conventional solutions where the PLL starting frequency is set to a minimum programmable frequency (for a DC-DC converter, for instance) with non-negligible ripple on the out voltage (Vout) and current until the PLL circuit “locks” again the external clock.

That is, in solutions as disclosed herein a transition occurs without frequency “jumps” and the ripple on the output voltage Vout just slowly increases due to a lower switching frequency, with a smooth transition to the new operating point is performed.

By way of contrast, in conventional solutions, where he PLL starting frequency is set to a minimum programmable frequency equal to the frequency of the external clock, the resulting transition may be fast, but a frequency jump may occur with the consequence of generating an significant ripple on the out voltage Vout.

To summarize:
oscillators configured to operate both in a free running mode and with an associated PLL exhibit problems related to frequency locking time and a possible discontinuity in the frequency domain due to the switching between a self-programmed frequency for the oscillator in a free running mode and PLL operation. This results in undesired frequency swings caused by phase “jumps” and non-negligible times required for PLL lock-up;
solutions as disclosed herein facilitate achieving a fast PLL locking time, with frequency linearity and soft PLL startup and no undesired frequency swings if the external clock presents similar frequency to the internal self-generated clock; frequency discontinuities are avoided when switching between a free running mode of the oscillator and PLL mode;
in solutions as disclosed herein, the PLL circuitry is operated in a close loop also when the system operates paced by an internal clock, keeping a PLL control node at same level expected to be set by an external clock with a same frequency of the internal clock; locking time is reduced corresponding thereto;
these advantages are achieved via a simple modification of charge pump architecture, for instance exploiting switches such as p-channel MOSFET transistors in a charge pump as pass devices of a voltage/current feedback loop in order to pre-bias a PLL control voltage node at a same voltage level of a reference voltage provided to the oscillator in a free running mode.

Without prejudice to the underlying principles, the details and embodiments may vary, even significantly, with respect to what has been described by way of example only, without departing from the extent of protection.

The extent of protection is determined by the annexed claims.

1. A circuit, comprising:
a phase detector configured to detect a phase difference between an input clock signal applied to a first input and a further clock signal applied to a second input;
a charge pump configured to produce a phase-lock control signal;
a voltage-controlled oscillator configured to produce a pulsed output signal at an output node in response to a voltage control signal;
a feedback loop from the output node of the voltage-controlled oscillator to the second input of the phase detector, wherein said feedback loop generates the further clock signal in response to the pulsed output signal from the voltage-controlled oscillator, and
switch circuitry configured to switch the circuit from a first circuit configuration to a second circuit configuration, wherein:
in the first circuit configuration, said voltage control signal for the voltage-controlled oscillator is a reference voltage, and the charge pump is decoupled from an output of the phase detector and configured to regulate the phase-lock control signal at said reference voltage; and
in the second circuit configuration, the charge pump is coupled to the output of the phase detector and configured to produce said phase-lock control signal based on said phase difference detected by the phase detector and the voltage-controlled oscillator is configured to receive said phase-lock control signal generated from the charge pump as said voltage control signal.

2. The circuit of claim 1, further comprising a multiplexer coupled to the voltage-controlled oscillator and configured to apply as said voltage control signal a signal selected out of:
said reference voltage in the first circuit configuration; and
said phase-lock control signal from the charge pump in the second circuit configuration.

3. The circuit of claim 1, further comprising a low-pass filter configured to filter the phase-lock control signal from the charge pump.

4. The circuit of claim 1, wherein the charge pump comprises a first electronic switch and a second electronic switch arranged in series in a common current flow line with a node on said common current flow line between the first electronic switch and the second electronic switch, wherein, in response to the charge pump being coupled to the phase detector in the second circuit configuration, the first electronic switch and the second electronic switch are configured to be alternately made conductive and non-conductive, and wherein the phase-lock control signal based on said phase difference is derived from said node on said common current flow line between the first electronic switch and the second electronic switch.

5. The circuit of claim 4, further comprising a differential stage configured to receive as inputs said reference voltage and said phase-lock control signal derived from said node on the common current flow line between the first electronic switch and the second electronic switch, and wherein, in response to the charge pump being decoupled from the phase detector in the first circuit configuration, the output from the differential stage is applied to a control terminal of the first electronic switch in the charge pump, and wherein, in the first circuit configuration, said phase-lock control signal is regulated to said reference voltage.

6. The circuit of claim 5, wherein the switch circuitry is configured to force the second electronic switch in the charge pump to a conductive state in said first circuit configuration.

7. The circuit of claim 1, wherein the charge pump circuit, comprises:
a first electronic switch controlled by a first control signal;
a second electronic switch controlled by a second control signal and arranged in series with, and connected to, the first electronic switch at a node;
a switching circuit configured to generate the first control signal as one of: a pump up control signal output from the phase detector when the PLL circuit is in an on mode of operation and a difference signal when the PLL circuit is in an off mode of operation;
a differential amplifier configured to generate the difference signal as a difference between a reference signal and a signal output at the node; and
a logic gate configured to generate the second signal as a logical combination of a pump down control signal output from the phase detector and a signal indicating that the PLL circuit is in the off mode of operation.

8. The circuit of claim 7, wherein the charge pump circuit further comprises a third first electronic switch coupled between a source terminal of the second electronic switch and ground, the third electronic switch controlled by a first control signal indicating that the PLL circuit is in the on mode of operation.

9. The circuit of claim 8, wherein the logic gate is a logical OR gate.

10. A method of operating a phase-locked loop (PLL) circuit that includes a phase detector configured to detect a phase difference between an input clock signal and a further clock signal, a charge pump configured to produce a phase-lock control signal, a voltage-controlled oscillator configured to produce a pulsed output signal based on a voltage control signal applied thereto, and a feedback loop generating said further clock signal in response to the pulsed output signal, the method comprising:
in a first circuit configuration, applying a reference voltage the voltage-controlled oscillator as said voltage control signal, decoupling the charge pump from an output of the phase detector, and regulating the phase-lock control signal at said reference voltage;
switching the PLL circuit from the first circuit configuration to a second circuit configuration;
in the second circuit configuration, coupling the charge pump to the output of the phase detector, producing said phase-lock control signal based on said phase difference from the phase detector, and applying said phase-lock control signal from the charge pump to the voltage-controlled oscillator as said voltage control signal.

11. The method of claim 10, further comprising low-pass filtering the phase-lock control signal from the charge pump.

12. The method of claim 10, wherein the charge pump includes a first electronic switch and a second electronic switch arranged in series in a common current flow line with a node on said common current flow line between the first electronic switch and the second electronic switch, the method comprising:
in the second circuit configuration, coupling the charge pump to the phase detector, alternately making the first electronic switch and the second electronic switch conductive and non-conductive, and generating the phase-lock control signal based on said phase difference which is derived from said node on said common current flow line between the first electronic switch and the second electronic switch.

13. The method of claim 12, further comprising:
controlling the first electronic switch using a differential stage which receives said reference voltage and said phase-lock control signal derived from said node on the common current flow line between the first electronic switch and the second electronic switch;
in the first circuit configuration, decoupling the charge pump from the phase detector, and applying the output from the differential stage to a control terminal of the first electronic switch in the charge pump wherein, in the first circuit configuration, said phase-lock control signal is regulated to said reference voltage.

14. The method of claim 13, further comprising forcing the second electronic switch in the charge pump to a conductive state in said first circuit configuration.

15. A charge pump circuit for a phase-locked loop (PLL) circuit, comprising:
a first electronic switch controlled by a first control signal;
a second electronic switch controlled by a second control signal and arranged in series with, and connected to, the first electronic switch at a node;
a switching circuit configured to generate the first control signal as one of: a pump up control signal when the PLL circuit is in an on mode of operation and a difference signal when the PLL circuit is in an off mode of operation;
a differential amplifier configured to generate the difference signal as a difference between a reference signal and a signal output at the node; and
a logic gate configured to generate the second signal as a logical combination of a pump down control signal and a signal indicating that the PLL circuit is in the off mode of operation.

16. The charge pump circuit of claim 15, further comprising a third first electronic switch coupled between a source terminal of the second electronic switch and ground, the third electronic switch controlled by a first control signal indicating that the PLL circuit is in the on mode of operation.

17. The charge pump circuit of claim 15, wherein the logic gate is a logical OR gate.

18. The charge pump circuit of claim 15, wherein the pump up control signal and pump down control signal are generated by a phase detector circuit of the PLL circuit.

19. The charge pump circuit of claim 15, wherein the signal output at the node is filtered by a low pass filter of the PLL circuit.
